(19) United States
(12) Patent Application Publication
(10) Pub. No.: US 2024/0396238 A1
(43) Pub. Date: Nov. 28, 2024

(54) CONTACT SUPPORT FOR AN INTEGRATED CIRCUIT

(71) Applicant: VALEO SYSTEMES D'ESSUYAGE, La Verriere (FR)

(72) Inventors: Siegfried STEFANI, BIETIGHEIM-BISSINGEN (DE); Harald KAPITZA, BIETIGHEIM-BISSINGEN (DE); Timo RUKWID, BIETIGHEIM-BISSINGEN (DE)

(73) Assignee: VALEO SYSTEMES D'ESSUYAGE, La Verriere (FR)

(21) Appl. No.: 18/694,499

(22) PCT Filed: Jul. 27, 2022
(86) PCT No.: PCT/EP2022/071128

§ 371 Date: Mar. 22, 2024

(30) Foreign Application Priority Data
Sep. 22, 2021 (FR) FR2109954

(51) Int. Cl. H01R 12/58; B60S 1/08; H05K 1/18

(52) U.S. Cl. CPC H01R 12/58; B60S 1/08; H05K 1/181; H05K 2201/10015; H05K 2201/10295

(57) ABSTRACT

The invention relates to a contact retention device for an integrated circuit including a common substrate having a hole extending through the common substrate. The contact retention device includes a support part suitable for being fixed to the common substrate and including an orifice suitable for being aligned with the hole, and a retention piece fixed to the support piece and centered by the orifice. The retention part includes an upper part suitable for guiding an insertion of an electrical conductor into the orifice, a lower part suitable for forming an elastic contact between the inserted electrical conductor and the retention part, and a middle part arranged between the upper part and the lower part. The middle part and the lower part are suitable for being inserted into the hole.

### TECHNICAL FIELD

The present invention relates to the field of electronic components for an integrated circuit, and more specifically relates to contact holders for an integrated circuit, the integrated circuits comprising such a contact holder and the arrangements of DC motors for an automotive windshield wiper comprising such an integrated circuit.

### BACKGROUND OF THE INVENTION

The level of integration of electronic integrated circuits becomes higher every year. In order to meet this exacting requirement, it is well known that the physical dimension of the electronic components has been reduced. For the same reason, the physical distance between the electronic components in an integrated circuit also must be significantly reduced.

In general, contact retention for an integrated circuit is designed to provide a reliable electrical contact between an electrical conductor, such as an electrical wire, and an electrical pin of an integrated circuit.

However, this electrical conductor often must be soldered to the contact holder in order to ensure good electrical contact, which requires an additional manufacturing step and is not very practical for some electrical devices requiring rapid manual installation.

Some contact holders exist that allow electrical conductors to be manually inserted into the contact holder. However, it is not always easy to determine an appropriate angle for this manual insertion of electrical conductors.

In addition, even with an appropriate angle, it can still be difficult to maintain or guarantee this appropriate angle after manual insertion.

Consequently, the contact holders may not be disposed optimally during or after the manual insertion of the electrical conductors, and the performance capabilities of the contact holders therefore cannot be optimized.

Therefore, a requirement exists to provide a simple and more reliable technical solution that equally ensures less error-prone manual insertion of the electrical conductor into the contact holder and more reliable and more optimized electrical contact between the inserted electrical conductor and the contact holder after manual insertion of the electrical conductor.

### SUMMARY OF THE INVENTION

Unless otherwise defined, all terms (including technical and scientific terms) used in the present document should be interpreted in terms of their use in the art. It is also understood that terms in common use also should be interpreted in the usual way in the relevant art and not in an idealized or overly formal sense, unless expressly defined as such in the present document.

Throughout the present text, the term “comprises” and derivatives thereof (such as “comprising”, etc.) should not be understood in an exclusive sense, i.e., these terms should not be interpreted as excluding the possibility that what is described and defined may include other elements, steps, etc.

According to one aspect, a contact retention device is proposed for an integrated circuit comprising a common substrate having a hole passing through the common substrate.

The contact retention device comprises a support part adapted to be fixed to the common substrate and comprising an orifice adapted to be aligned with the hole, and a retention part fixed to the support part and centered by the orifice. The retention part comprises an upper part adapted to guide the insertion of an electrical conductor into the orifice, a lower part adapted to form a resilient contact between the inserted electrical conductor and the retention part, and a median part disposed between the upper part and the lower part. The median part and the lower part are adapted to be inserted into the orifice.

Such a contact holder for an integrated circuit advantageously allows guided manual insertion of the electrical conductor by means of the upper part of the retention part. In this way, an appropriate insertion angle of the electrical conductor can be guaranteed so as to reduce the risk of damaging the contact holder when inserting the electrical conductor.

Furthermore, the lower part of the retention part is adapted to form a resilient contact between the inserted electrical conductor and the retention part.

Consequently, the upper part and the lower part allow the appropriate angle to be maintained between the inserted electrical conductor and the contact holder, even after manual insertion.

According to one embodiment, the upper part comprises at least two conical shaped metal clips folded away from the center of the orifice.

Such folded metal clips can safely guide the electrical conductor, such as an electrical wire, to be inserted into the orifice.

For example, the lower part can comprise a plurality of metal clips folded toward the center of the orifice and the lower part is adapted to remain inside the hole when the lower part and the median part are inserted into the hole.

The folded metal clips of the lower part advantageously can securely hold the electrical conductor once it is inserted into the contact holder. Furthermore, the lower part and the upper part can guarantee an appropriate angle for the manual insertion of the electrical conductor. Since the lower part is adapted to remain inside the hole, the lower part is advantageously protected by the hole, the performance of the contact holder can be better ensured.

According to another embodiment, the support part comprises a flat portion centered by the orifice and adapted to be soldered onto an upper surface of the common substrate, and a cylindrical portion centered by the orifice and adapted to be inserted into the hole, with the median part being fixed to the cylindrical portion by an interference fit.

The upper part can comprise, for example, six conical shaped metal clips folded from the center of the orifice.

By way of a non-limiting example, the support part and the retention part are formed as a single metal part, which can advantageously reduce the complexity and the manufacturing cost of the contact retention.

According to another embodiment, the support part comprises a cylindrical body comprising a plurality of openings and a conical end disposed at one end of the cylindrical body, the conical end being adapted to be inserted through the hole and the cylindrical body being adapted to be inserted into the hole and to be fixed to the common substrate by an interference fit, the upper part being disposed at the other end of the cylindrical body, the median part being formed by part of the cylindrical body close to the other end of the cylindrical body, and the lower part comprising a plurality of metal clips folded toward the center of the orifice, each metal clip being formed in a corresponding opening of the cylindrical body.

In this embodiment, the lower part is advantageously integrated into the openings of the cylindrical body of the support part, which is adapted to be inserted into the hole and to be fixed to the common substrate by an interference fit. Consequently, no soldering step is necessary and the support part and the retention part are formed as a single piece.

According to another embodiment, the support part comprises a cylindrical body adapted to be inserted into the hole and a plurality of flat metal clips disposed at one end of the cylindrical body, each flat metal clip being adapted to be soldered onto an upper surface of the common substrate, the upper part being formed at the end of the cylindrical body, the median part being formed by the cylindrical body, and the lower part being formed at the other end of the cylindrical body.

According to another aspect, an integrated circuit is proposed.

The integrated circuit comprises a common substrate having a hole passing through the common substrate, and a contact retention element as defined above. The support part is fixed to the common substrate and the median part and the lower part of the retention part are inserted into the hole.

According to yet another aspect, a DC motor arrangement is proposed for an automotive windshield wiper. The DC motor arrangement comprises an integrated circuit as defined above.

### BRIEF DESCRIPTION OF DRAWINGS

In order to complete the description, and in order to better understand the invention, a set of drawings is provided. These drawings form an integral part of the description and illustrate an embodiment of the invention, which must not be interpreted as limiting the scope of the invention, but only as an embodiment of the invention. The drawings comprise the following figures:

FIG. 1 shows an exploded view of a filtration unit comprising a first contact retention device and a second contact retention device according to the invention;

FIG. 2 shows a general view of the first contact retention device according to the invention;

FIG. 3 shows a front view of the first contact retention device installed on a printed circuit board;

FIG. 4 shows a K-K cross-sectional view of FIG. 4;

FIG. 5 shows a general view of the second contact retention device according to the invention;

FIG. 6 shows a front view of the second contact retention device installed on a printed circuit board;

FIG. 7 shows an L-L cross-sectional view of FIG. 6;

FIG. 8 shows a general view of a third contact retention device according to the invention;

FIG. 9 shows a front view of the third contact retention device installed on a printed circuit board;

FIG. 10 shows an O-O cross-sectional view of FIG. 9;

FIG. 11 shows an exploded view of a DC motor arrangement for an automotive windshield wiper comprising a filtration unit according to the invention;

FIG. 12 shows a C-C cross-sectional view of FIG. 11.

### DETAILED DESCRIPTION OF THE INVENTION

The embodiments are described with sufficient details to allow individuals with ordinary skill in the art to produce and implement the systems and methods described in the present document. It is important to understand that the embodiments can be provided in many other forms and should not be interpreted as being limited to the examples presented herein.

Consequently, although the embodiment can be modified in various ways and can assume various alternative embodiments, specific embodiments thereof are shown in the drawings and are described in detail hereafter by way of examples. There is no intention to be limited to the particular embodiments that are disclosed. On the contrary, all the modifications, all the equivalents and all the alternatives falling within the scope of the appended claims must be included. The elements of the embodiments are systematically denoted using the same reference numerals throughout the drawings and detailed description, where applicable.

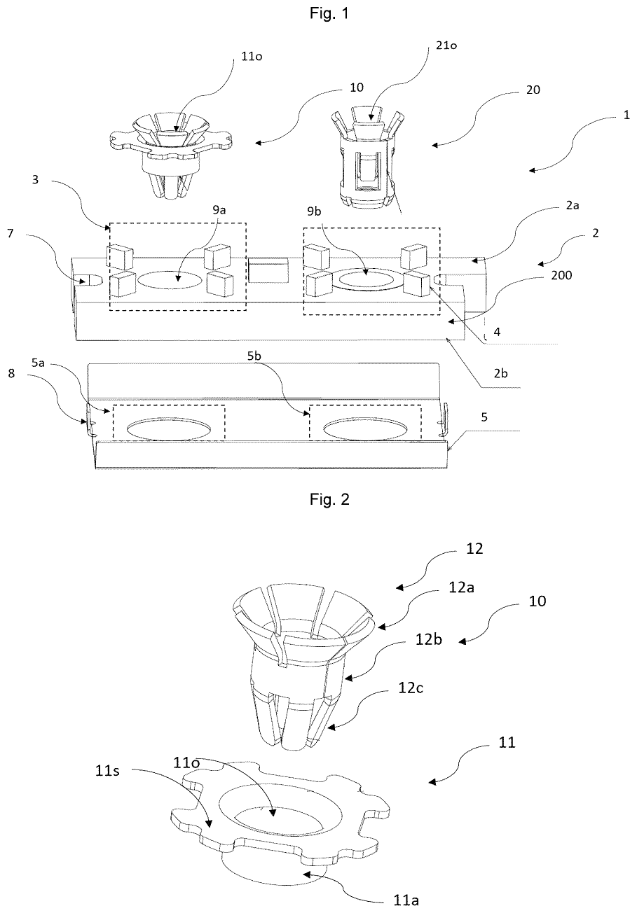

FIG. 1 illustrates an electronic application, for example, a filtration unit 1 used in a DC motor device.

The filtration unit 1 comprises an integrated circuit 2, in the form of a printed circuit board 2, which comprises a common substrate 200 having a first layer, in this case a front layer 2a, and at least one second layer, in this case a rear layer 2b.

The filtration unit 1 comprises:
a first filtration means 3 comprising four capacitors, for example;
a second filtration means 4 also comprising four capacitors;
a first contact retention device 10, and a second contact retention device 20, which are configured to be disposed in the front layer 2a in order to respectively route the capacitors of the first and second filtration means 3, 4.

The first contact retention device 10 and the second contact retention device 20 can be produced in the same manner, or in a different manner, as illustrated in FIG. 1. The description of the first and second contact retention devices 10, 20 will be described throughout the remainder of the text.

For example, all the capacitors included in the first and second filtration means 3, 4 are multilayer ceramic capacitors (MLCC) designed as surface-mounted devices (SMD), which allow a good packaging size and low parasitic inductance to be provided.

The filtration unit 1 further comprises a metal plate 5 electrically connected to the rear layer 2b of the integrated circuit 2. The first and second filtration means 3, 4 are respectively connected to a first part 5a and a second part 5b of the metal plate 5.

The metal plate 5 is intended to be soldered onto the rear layer 2b of the integrated circuit 2. The integrated circuit 2 comprises at least one notch 7 intended to receive a corresponding projection 8 of the metal plate 5. This interconnection between the projection 8 and the notch 7 is useful during the process of soldering the metal plate 5 to the rear layer 2b of the integrated circuit 2, where an attachment is required in order to avoid unwanted movement of the metal plate 5 relative to the integrated circuit 2.

The integrated circuit 2 further comprises a first hole 9a and a second hole 9b passing through the common substrate 200. The first hole 9a and the second hole 9b are respectively adapted to receive the first contact retention device 10 and the second contact retention device 20.

Each contact retention device 10, 20 comprises an orifice 110, 210 intended to receive a corresponding electrical conductor, in this case a DC motor power supply line, and arranged to sealably hold the corresponding DC motor power supply line, thus connecting each DC motor power supply line to the corresponding first and second filtration means 3, 4.

Such a filtration unit 1 comprising the first and second contact supports 10, 20 is particularly suitable for applications with limited space.

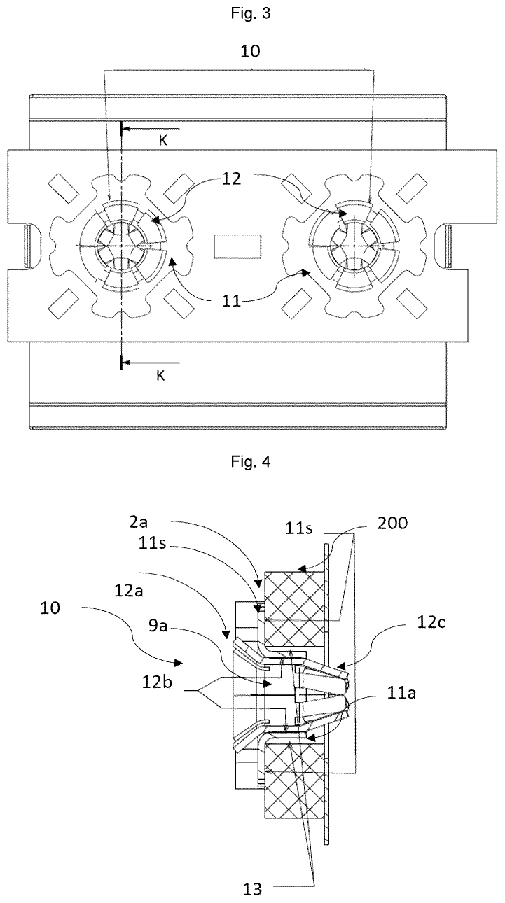

Reference will now be made to FIG. 2, FIG. 3, and FIG. 4 to describe the first contact retention device 10 in detail.

The first contact retention device 10 comprises a support part 11 adapted to be fixed to the common substrate 200. The support part 11 comprises a first orifice 110 adapted to be aligned with the first hole 9a, a support surface 11s having a plurality of grooves, and a cylindrical body 11a having a cylindrical shape and being centered by the first orifice 110. The cylindrical body 11a is adapted to be inserted into the first hole 9a and the support surface 11 is adapted to be soldered onto the front layer 2a.

FIG. 3 shows a front view of two first contact retention devices 10 installed on the common substrate 200. The shape and the position of the grooves of the support surface 11s are adapted to receive the capacitors of the first filtration means 3.

FIG. 4 illustrates a K-K cross-sectional view of FIG. 3. The support part 11 is inserted into the first hole 9a. Since the support surface 11s is then soldered onto the front layer to ensure reliable fastening and a reliable electrical contact between the support part 11 and the front layer 2a, it is possible to have a certain amount of assembly clearance between the cylindrical body 11a and the first hole 9a, as shown in FIG. 4.

The first contact retention device 10 further comprises a retention part 12, which in this case is a part separate from the support part 11.

The retention part 12 is arranged to be pre-assembled by an interference fit in the support part 11, as can be seen in FIG. 1, and comprises an upper part 12a, a median part 12b and a lower part 12c.

The upper part 12a comprises at least two metal clips, in this case six metal clips, for example. These metal clips are conical shaped and are slightly curved relative to the center of the first orifice 110. These metal clips are thus adapted to guide the insertion of an electrical conductor into the first orifice 110.

The median part 12b comprises a metal cylindrical portion. The diameter of this cylindrical portion is adapted to cooperate with the support part 11 so that the median part 12b can be pre-assembled in the support part 11 by an interference fit and can be centered by the first orifice 110. The assembly by an interference fit between the median part 12b and the support part 11 also allows a reliable electrical contact to be provided between the retention part 12 and the support part 11.

The lower part 12c comprises a plurality of metal clips folded toward the center of the first orifice 110. These metal clips are, for example, resilient contact clips on the circumference. When an electrical conductor is inserted into the retention part 12 and through the lower part 12c, the first contact retention device 10 can not only correctly guide the manual insertion of the electrical conductor, but can also maintain a correct insertion angle after manual insertion.

When the lower part 12c and the median part 12b are assembled in the support part 11 that is soldered onto the front layer 2a, as illustrated in FIG. 4, the lower part 12c partially protrudes from the rear layer 2b in order to maintain an appropriate manual insertion angle for the electrical conductor once inserted into the first contact retention device 10.

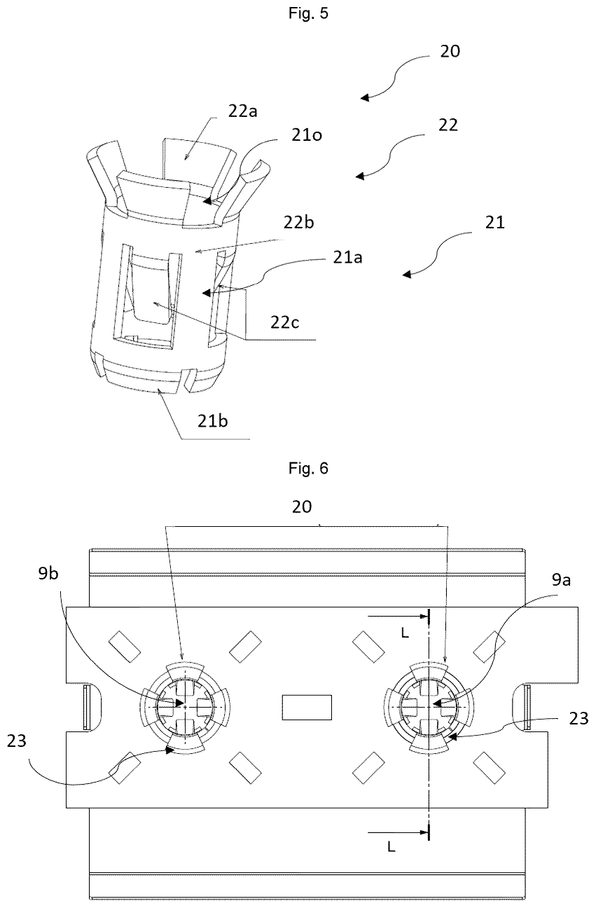

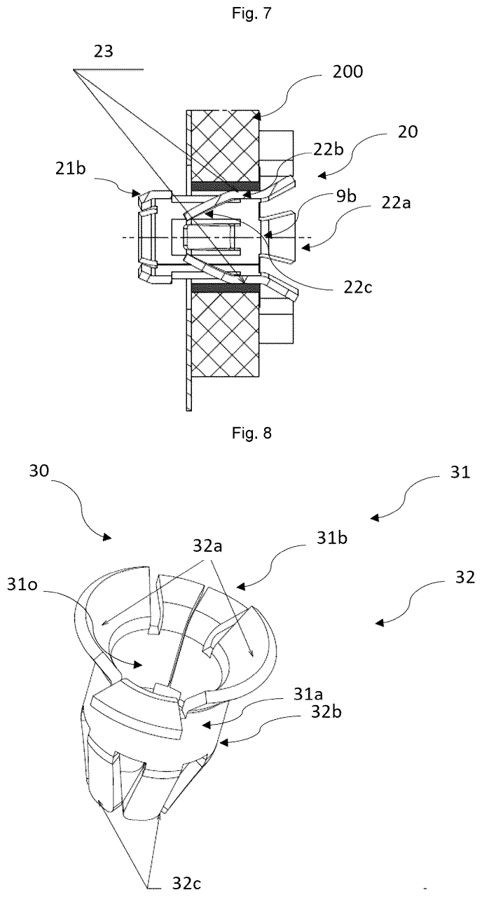

Reference will now be made to FIG. 5, FIG. 6, and FIG. 7 to describe the second contact retention device 20 in detail.

The second contact retention device 20 comprises a support part 21 and a retention part 22, which are centered by a second hole 9b and are formed in a single metal part.

The support part 21 comprises a cylindrical body 21a comprising a plurality of openings, in this case four openings, for example, and a conical end 21b disposed at one end of the cylindrical body 21a. The conical end 21b is configured to facilitate the insertion of the second contact retention device 20 into a corresponding hole, for example, the second hole 9b in FIG. 1 and FIG. 6.

It should be noted that the second contact retention device 20 does not need to be soldered to the common substrate 200. In order to ensure a good electrical contact, an electrically conductive via 23 of the printed circuit is generally used in the second hole 9b, as illustrated in FIG. 6.

The internal dimension of the via 23 of the printed circuit board is slightly less than the external dimension of the cylindrical body 21a of the support part 21 so that the support part 21 can be assembled in the via 23 by an interference fit, as can be seen in FIG. 7.

The retention part 22 comprises an upper portion 22a disposed at the other end of the cylindrical body 21a and comprising a plurality of conical shaped metal clips folded toward the center of the second orifice 210, a median part 22b formed by part of the cylindrical body 21a close to the other end of the cylindrical body 21a, and a lower part 22c comprising a plurality of resilient metal clips, in this case four metal clips, for example, circumferentially folded toward the center of the second hole 9b. Each metal clip is formed in a corresponding opening of the cylindrical body 21a.

The metal clips of the upper part 22a are adapted to guide the insertion of an electrical conductor into the second orifice 210 and these resilient metal clips of the lower part 22c are advantageously disposed in order to maintain an appropriate angle for the manual insertion of an electrical conductor.

As illustrated in FIG. 7, the lower part 22c of the second contact retention device 20 remains inside the second hole 9b when the second contact retention device 20 is assembled in the second hole 9b so as to improve the rigidity of the second contact retention device 20.

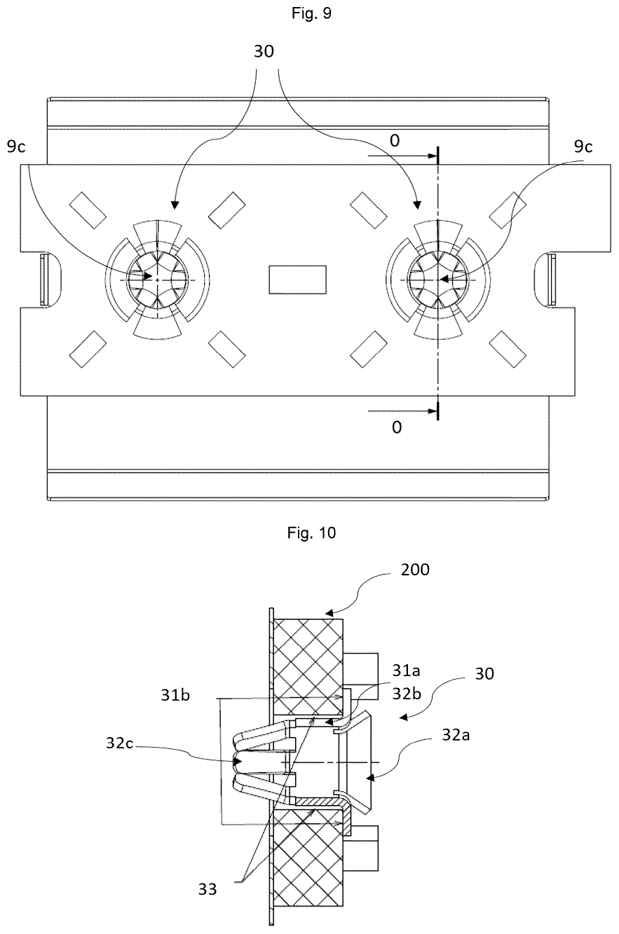

FIG. 8, FIG. 9 and FIG. 10 relate to the presentation of another embodiment of the contact retention device, in this case called third contact retention device 30.

The third contact retention device 30 comprises a support part 31 and a retention part 32, which are centered by a third orifice 9c and are formed in a single metal part.

The support part 31 of the third contact retention device 30 comprises a cylindrical body 31a and a plurality of flat metal clips 31b, in this case two flat metal clips, for example, disposed at one end of the cylindrical body 31a. Each flat metal clip is centered by a third orifice 310 and is adapted to be soldered onto an upper surface of the common substrate 200, in this case, for example, onto the front layer 2a of the common substrate 200. The cylindrical body 31a is adapted to be inserted into a hole passing through the common substrate 200, in this case, for example, the third hole 9c of the common substrate 200.

Since the support part 31 is fixed to the front layer 2a by soldering the flat metal clips 31b, the support part 31 can be reliably fixed in the third hole 9c and have a reliable electrical contact with the front layer 2a of the common substrate 200. In addition, an assembly clearance 33 can be provided between the cylindrical body 31a and the third hole 9c, as can be seen in FIG. 10.

The retention part 32 of the third contact retention device 30 comprises an upper portion 32a formed at said end of the cylindrical body 31a, for example, in the form of two resilient metal clips folded from the center of the third orifice 310.

These resilient metal clips of the upper part 32a are disposed on the periphery in addition to the flat metal clips 31b and are adapted to guide the insertion of an electrical conductor into the third orifice 310.

The retention part 32 of the third contact retention device 30 further comprises a median part 32b formed by the cylindrical body 31a and a lower part 32c formed at the other end of the cylindrical body 31a.

As for the first or second contact retention device 10, 20, the lower part 32c of the third contact retention device 30 is adapted to form a resilient contact between the inserted electrical conductor and the retention part 32. For example, the lower part comprises six resilient metal clips folded toward the center of the third orifice 310. The function and the advantage of the lower part 32c of the third contact retention device 30 are the same as those of the first and second contact retention devices 10 and 20.

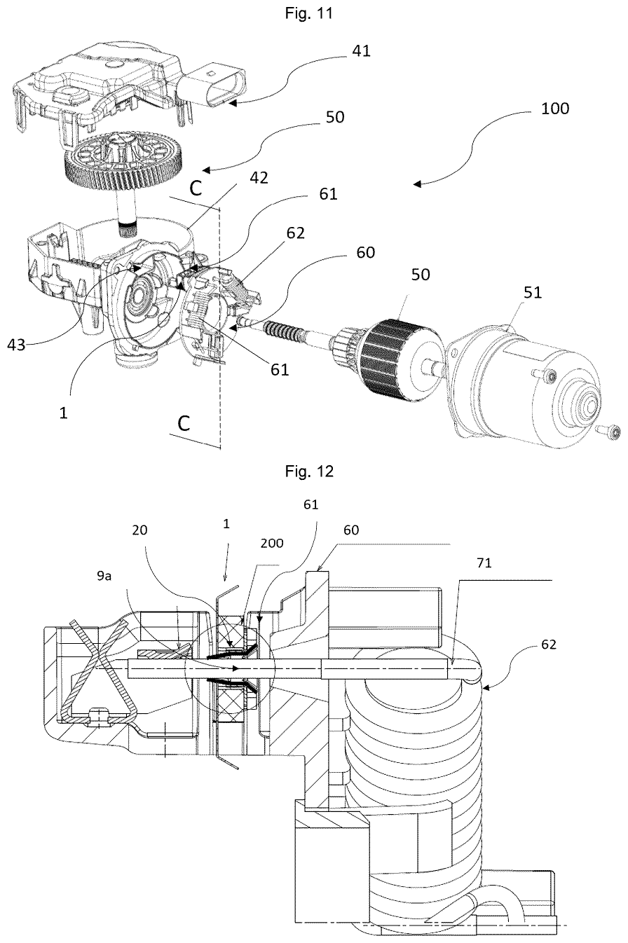

Reference will now be made to FIG. 11 to illustrate a DC motor arrangement 100 for an automotive windshield wiper comprising a filtration unit 1 as shown in FIG. 1.

The DC motor arrangement 100 comprises:
a first part of a casing 41, in this case a gear cover, for example, and a second part of a casing 42, in this case a gear housing, for example;
a DC motor 50 intended to be covered by a motor casing 51 and to be located inside the first part of the casing 41;
a filtration unit 1 associated with the DC motor 50 in order to reduce the electromagnetic noise caused by this DC motor 50.

The DC motor arrangement 100 further comprises a brush board 60, a first inductor 61, a second inductor 62, a first power supply line, and a second power supply line of the DC motors 50.

The brush board 60 comprises a slot 61 that houses the filtration unit 1. Part of this brush board 60, comprising the slot 61, is intended to be inserted into an opening 43 of the gear casing 42. The metal plate 5 of the filtration unit 1 is adapted to partially close this opening 43 by coming into contact with the second portion of the casing 42.

The metal plate 5, the second part of the casing 42 and the first part of the casing 41 thus form an electromagnetic shield, commonly called a Faraday shield or Faraday cage, for the DC motor 50 so as to improve the electromagnetic compatibility EMC performance capabilities of the DC motor arrangement 100.

FIG. 12 shows a C-C cross-sectional view of the DC motor device 100 when the DC motor arrangement 100 is assembled.

The filtration unit 1 is actually installed in the slot 61 of the brush board 60. An electrical conductor 71, in this case an electrical wire 71 of the second inductor 62 of the brush board 60, in this case is inserted, for example, into the first hole 9a of the common substrate 200 through the first contact retention device 10.

As is clearly illustrated in FIG. 12, the retention part 12 of the first contact retention device 10 can not only easily guide the manual insertion of the electrical wire, but can also maintain an appropriate insertion angle for the electrical wire.

What is claimed is:

1. A contact retention device for an integrated circuit including a common substrate having a hole passing through the common substrate, the contact retention device comprising:
a support part adapted to be fixed to the common substrate and including an orifice adapted to be aligned with the hole; and
a retention part fixed to the support part and centered by the orifice, the retention part including an upper part adapted to guide the insertion of an electrical conductor into the orifice, a lower part adapted to form a resilient contact between the inserted electrical conductor and the retention part, and a median part disposed between the upper part and the lower part, the median part and the lower part being adapted to be inserted into the hole.

2. The contact retention device as claimed in claim 1, wherein the upper part includes at least two conical shaped metal clips folded away from the center of the orifice

3. The contact retention device as claimed in claim 1, wherein the lower part includes a plurality of metal clips folded toward the center of the orifice.

4. The contact retention device as claimed in claim 1, wherein the support part includes a flat surface centered by the orifice and adapted to be soldered onto an upper surface of the common substrate, and a cylindrical portion centered by the orifice and adapted to be inserted into the hole, the median part being fixed to the cylindrical portion by an interference fit.

5. The contact retention device as claimed in claim 4, wherein the upper part includes six conical shaped metal clips folded away from the center of the orifice.

6. The contact retention device as claimed in claim 1, wherein the support part and the retention part are formed as a single metal part.

7. The contact retention device as claimed in claim 6, wherein the support part includes a cylindrical body including a plurality of openings and a conical end disposed at one end of the cylindrical body, the conical end being adapted to be inserted through the hole and the cylindrical body being adapted to be inserted into the hole and to be fixed to the common substrate by an interference fit, the upper part being disposed at the other end of the cylindrical body, the median part being formed by part of the cylindrical body close to the other end of the cylindrical body, and the lower part including a plurality of metal clips folded toward the center of the orifice, each metal clip being formed in a corresponding opening of the cylindrical body.

8. The contact retention device as claimed in claim 6, wherein the support part includes a cylindrical body adapted to be inserted into the hole and a plurality of flat metal clips disposed at one end of the cylindrical body, each flat metal clip being adapted to be soldered onto an upper surface of the common substrate, the upper part being formed at the end of the cylindrical body, the median part being formed by the cylindrical body, and the lower part being formed at the other end of the cylindrical body.

9. An integrated circuit comprising:
a common substrate having a hole passing through the common substrate; and
a contact retention device including a support part adapted to be fixed to the common substrate and including an orifice adapted to be aligned with the hole, and a retention part fixed to the support part and centered by the orifice, the retention part including an upper part adapted to guide the insertion of an electrical conductor into the orifice, a lower part adapted to form a resilient contact between the inserted electrical conductor and the retention part, and a median part disposed between the upper part and the lower part, the median part and the lower part being adapted to be inserted into the hole, the support part being fixed to the common substrate, and the median part and the lower part of the retention part being inserted into the hole.

10. A DC motor arrangement for an automotive windshield wiper comprising an integrated circuit including a common substrate having a hole passing through the common substrate, and a contact retention device including a support part adapted to be fixed to the common substrate and including an orifice adapted to be aligned with the hole, and a retention part fixed to the support part and centered by the orifice, the retention part including an upper part adapted to guide the insertion of an electrical conductor into the orifice, a lower part adapted to form a resilient contact between the inserted electrical conductor and the retention part, and a median part disposed between the upper part and the lower part, the median part and the lower part being adapted to be inserted into the hole, the support part being fixed to the common substrate, and the median part and the lower part of the retention part being inserted into the hole, the median part and the lower part being adapted to be inserted into the hole, the support part being fixed to the common substrate, and the median part and the lower part of the retention part being inserted into the hole.
